(19) United States
(12) Patent Application Publication
(10) Pub. No.: US 2022/0368376 A1
(43) Pub. Date: Nov. 17, 2022

(54) RESONATOR ARRAY SENSOR ARRANGEMENT

(71) Applicant: Hitachi Energy Switzerland AG, Baden (CH)

(72) Inventors: Gunnar RUSSBERG, Västerås (SE); Ener SALINAS, Västerås (SE); Lorenzo PRIETO, Cordoba (ES)

(73) Assignee: Hitachi Energy Switzerland AG, Baden (CH)

(21) Appl. No.: 17/623,215

(22) PCT Filed: Jun. 25, 2020
(86) PCT No.: PCT/EP2020/067895

§ 371 Date: Dec. 27, 2021

(30) Foreign Application Priority Data
Jun. 28, 2019 (EP) 19183250.0

(51) Int. Cl. H04B 5/00; H02J 50/12; G01R 27/26

(52) U.S. Cl. CPC H04B 5/0037; H02J 50/12; H04B 5/0075; G01R 27/26

(57) ABSTRACT

The present disclosure relates to a high voltage, HV, electrical device comprising a sensor arrangement including a sensor configured to measure a property of the electrical device, a detector configured to receive signals from the sensor, an electrical power source, and a resonator array including an array of LC circuits arranged equidistantly from each other along a transfer path, such as an axis, between the sensor and the detector and configured to wirelessly transfer power to the sensor from the electrical power source and to wirelessly transfer the sensor signals from the sensor to the detector.

### CROSS REFERENCE TO RELATED APPLICATIONS

This application is a 35 U.S.C. § 371 national stage application of PCT International Application No. PCT/EP2020/067895 filed on Jun. 25, 2020, which in turn claims foreign priority to European Patent Application No. 19183250.0, filed on Jun. 28, 2019, the disclosures and content of which are incorporated by reference herein in their entirety.

### TECHNICAL FIELD

The present disclosure relates to a sensor arrangement for measuring a property of an environment in an electrical device.

### BACKGROUND

Power transformers and other high-voltage (HV) devices typically involve components (core, conductors, paper insulation, structural elements, sensors, etc.) exposed to extreme conditions e.g. in an insulation-oil filled tank enclosure. This implies high electric field strengths due to voltage differences of tens or hundreds of kilovolts, elevated temperatures exceeding 100-130° C. due to losses in windings and magnetic core, structural forces and vibrations, support pressures of the order hundred MPa, magnetic fields of the order 1.5-2 T, etc. For the monitoring and control of a power transformer, strategically positioned sensors and means for their operation (powering and communication) are essential components. Sensor solutions can be wired (e.g., optical wire) or wireless (e.g., WiFi or Radio Frequency, RF & RFID). Conventional conducting wire sensor solutions are automatically ruled out since they will generally not comply with the HV insulation demands. Transfer of power and signal via fibre optic is possible, but a problem is that optical fibres are sensitive to mechanical stress.

Sensors and their means for operation should not reduce the transformer internal insulation strength or increase the risk for electrical breakdown. They should preferably fit into existing transformer designs with negligible demands for design alterations or extra space.

The harsh environment in which the sensing system has to work puts high demands on robustness and endurance, without becoming complex, bulky and/or expensive as many existing wireless (sensing and communication) solutions tend to be.

Sensor devices need access to an electric power supply during their entire life of operation. Traditional long life batteries are bulky and expensive. Passive (RF, RFID) wireless technologies, however, do not require batteries. RFID systems may feed both power to and signal from a sensing unit but are typically very short-range (a few dm). Required distances to bridge inside the transformer may be up to several meters, with associated accumulated potential differences of up to several hundred kilovolts.

Wireless power transfer from low voltage to high voltage can be achieved by means of resonator (inductance-capacitance, LC) coils to power e.g. sensors in a HV environments.

US 2017/167250 relates to wireless transfer of power and data down an oil or gas well to a pressure sensor using resonators. A first resonator is included in an inner tube coupled to a power source. A second resonator is included in an outer tube, outside of the inner tube, coupled to a sensor.

US 2010/177801 relates to a resonance array of temperature sensors for a jet engine or jet fuel tank.

US 2017/140870 discloses a HV insulator with embedded resonator coils. The resonator coils form a series of relay resonators that can be used for wireless power transfer and can provide the simultaneous functions of voltage insulation and wireless power transfer in a high-voltage environment such as that encountered in high-voltage power transmission line systems.

### SUMMARY

It is an objective of the present disclosure to provide an improved electrical device comprising a sensor arrangement for measuring a property of an environment in the electrical device, especially a HV environment.

According to an aspect of the present disclosure, there is provided a high voltage, HV, electrical device comprising a sensor arrangement comprising a sensor configured to measure a property of the electrical device, a detector configured to receive signals from the sensor, an electrical power source, and a resonator array comprising an array of LC circuits arranged equidistantly from each other along a transfer path, such as an axis, between the sensor and the detector and configured to wirelessly transfer power to the sensor from the electrical power source and to wirelessly transfer the sensor signals from the sensor to the detector.

According to another aspect of the present disclosure, there is provided a method of detecting a measured property in a high voltage, HV, electrical device, the method comprising by means of a resonator array comprising an array of LC circuits arranged equidistantly from each other along a transfer path, such as an axis, between a sensor and a detector, wirelessly transferring power from an electrical power source to the sensor, powering said sensor, and by means of the resonator array, wirelessly transferring signals indicating a measurement of the property from the sensor to the detector.

According to another aspect of the present disclosure, there is provided a computer program product comprising computer-executable components for causing a controller to perform an embodiment of the method of the present disclosure when the computer-executable components are run on processing circuitry comprised in the controller.

By the resonator array being arranged to both wirelessly transfer power to the sensor and to wirelessly transfer sensor signals to the detector, there is no need for a separate signal transfer arrangement such as via a Wireless Local Area Network (WLAN).

The term “high voltage” (HV) as used herein means a voltage greater than or equal to 1 kV. A high voltage environment is an environment produced during operation of said high voltage electric device, such that the high voltage electric device comprises a high voltage environment when in use.

It is to be noted that any feature of any of the aspects may be applied to any other aspect, wherever appropriate. Likewise, any advantage of any of the aspects may apply to any of the other aspects. Other objectives, features and advantages of the enclosed embodiments will be apparent from the following detailed disclosure, from the attached dependent claims as well as from the drawings.

Generally, all terms used in the claims are to be interpreted according to their ordinary meaning in the technical field, unless explicitly defined otherwise herein. All references to “a/an/the element, apparatus, component, means, step, etc.” are to be interpreted openly as referring to at least one instance of the element, apparatus, component, means, step, etc., unless explicitly stated otherwise. The steps of any method disclosed herein do not have to be performed in the exact order disclosed, unless explicitly stated. The use of “first”, “second” etc. for different features/components of the present disclosure are only intended to distinguish the features/components from other similar features/components and not to impart any order or hierarchy to the features/components.

### BRIEF DESCRIPTION OF THE DRAWINGS

Embodiments will be described, by way of example, with reference to the accompanying drawings, in which:

FIG. 1 is a schematic illustration of a sensor arrangement comprising a resonator array comprising a one-dimensional (1D) array of co-axial LC circuits, in accordance with an embodiment of the present disclosure.

FIG. 2 is a schematic illustration of a sensor arrangement comprising a resonator array comprising a one-dimensional (1D) array of co-planar LC circuits, in accordance with an embodiment of the present disclosure.

FIG. 3 is a schematic circuit diagram of a planar LC circuit printed on a film, in accordance with an embodiment of the present disclosure.

FIG. 4 is a schematic block diagram of a sensor arrangement, in accordance with an embodiment of the present disclosure.

FIG. 5 is a schematic block diagram of an electrical device comprising a sensor arrangement, in accordance with an embodiment of the present disclosure.

FIG. 6 is a schematic block diagram of a controller of a sensor arrangement, in accordance with an embodiment of the present disclosure.

FIG. 7 is a schematic flow chart of an embodiment of a method of the present disclosure.

### DETAILED DESCRIPTION

Embodiments will now be described more fully hereinafter with reference to the accompanying drawings, in which certain embodiments are shown. However, other embodiments in many different forms are possible within the scope of the present disclosure. Rather, the following embodiments are provided by way of example so that this disclosure will be thorough and complete, and will fully convey the scope of the disclosure to those skilled in the art. Like numbers refer to like elements throughout the description.

Embodiments of the disclosure aims at monitoring properties such as temperature and pressure in the harsh environment of high voltage devices such as power transformers without disturbing insulation properties and performance. However, embodiments of the disclosure may also be used for Low-Voltage (LV) or Medium-Voltage (MV) devices and environments thereof. Such monitoring requires transmitting power and signal relatively long distances, possibly across hundreds of kV electric potential. The sensor arrangement of the present disclosure may be regarded as a wireless monitoring system e.g. including i) at least one passive sensor unit in form of an LC-resonator with a natural frequency f depending sensitively on the property to be measured, ii) at least one array (one-, two- or three-dimensional, array) of LC-resonators with a fixed natural frequency f_{O} arranged with finite separation, and/or iii) power supplying and signal detection units (which may or may not be integrated with each other), e.g., an impedance analyser, inductively coupled to the sensor via the resonator array. Embodiments of the disclosure may provide robust and low-cost wireless transfer of power and sensor signals over several meters of distance without need for embedded energy storage or power harvesting in the electrical device.

Some embodiments provide that sensors and their means for operation should not reduce the internal insulation strength of the electrical device, e.g. a transformer, or in any way increase the risk for electrical breakdown. They should preferably fit into existing device designs with negligible demands for design alterations or extra space.

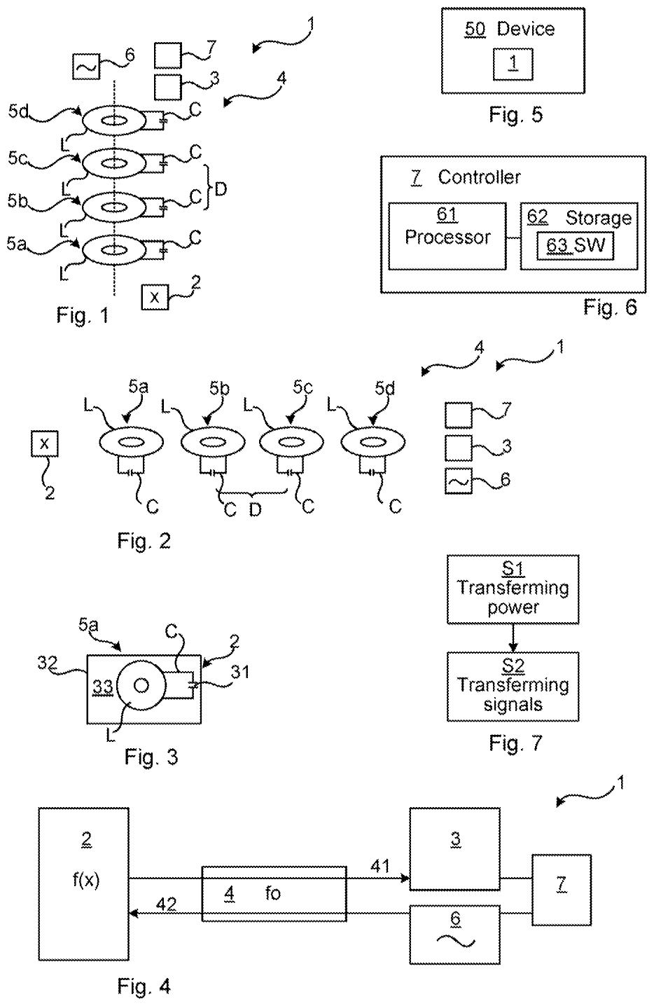

FIG. 1 illustrates an embodiment of a sensor arrangement 1 comprising a 1D resonator array 4 of a plurality of substantially flat (planar) LC circuits 5 (typically analogue LCR circuits with a small resistance, R), here four LC circuits 5a, 5b, 5c and 5d, arranged co-axially stacked on-top of each other an axial distance D equidistantly from each other along an axis (indicated as a dotted line in FIG. 1) which is orthogonal to the respective planes of the planar LC circuits 5. Each LC circuit 5 comprises an inductive circuit L and a capacitive circuit C comprising at least one capacitor.

The resonator array 4 is arranged to wirelessly transfer power from an alternating current (AC) electrical power source 6 to at least one sensor 2, powering said sensor, which sensor 2 is configured to measure a property x, e.g. temperature and/or pressure, of an environment in an electrical device, e.g. a HV environment within said electrical device. Additionally, the resonator array 4 is arranged to wirelessly transfer sensor signals, typically including information about the measured property x, from the sensor 2 to a detector 3. The detector 3 may e.g. be or comprise an impedance meter, including but not limited to an impedance analyser.

The sensor arrangement 1 may also comprise a controller 7 for controlling the operation of the sensor arrangement 1 (see also FIG. 6).

FIG. 2 illustrates another embodiment of a sensor arrangement 1. The sensor arrangement may be as discussed in relation to FIG. 1, but the resonator array is a 1D array of LC circuits 5 which are in a co-planar arrangement instead of a co-axial one. The substantially flat (planar) LC circuits 5 are arranged next to each other, substantially all in the same plane as the plane of each LC circuit. The LC circuits may be arranged equidistantly from each other along an axis between the sensor and the detector.

In addition to the example embodiments of FIGS. 1 and 2, it should be noted that the resonator array may follow a curved transfer path rather than a co-axial or co-planar path, as suitable for integrating the array in the electrical device and to power and signal transfers between the sensor 2 (e.g. at a high voltage) and the detector/power source at a more outer part (e.g. at a low or lower voltage) of the electrical device. In other words, the sensor may be arranged at a high electrical potential and the detector and/or the power source is/are arranged at a low electrical potential. In such a configuration, a low voltage (LV) may be defined as ground potential. It should also be noted that the resonator array may alternatively be a 2D or 3D array, though a 1D array may often be preferred. Further, it should be noted that the LC circuits may have any design and overall shape and need not be planar, though planar LC circuits may be preferred in some embodiments since they take up little space and may easily be printed on an electrically insulating substrate.

FIG. 3 illustrates an embodiment of an LC circuit 5 of a resonator array 4. The LC circuit can be formed on and/or in, e.g. by printing, an electrically insulating material 33, e.g. a dielectric material 33, e.g. in the form of a film 32, e.g. a flexible film which may facilitate integration of the array 4 in crammed spaces of the electrical device.

In some embodiments, the at least one sensor 2 is integrated with the resonator array 4, e.g. by being comprised in one of the LC circuits 5a of the array. The integrated sensor 2 may e.g. comprise a capacitor of the capacitive circuit C of the LC circuit 5a, e.g. the LC circuit furthest away from the detector 3. The capacitor of the integrated sensor may then comprise a material 31, e.g. a dielectric material, typically between its terminals, which is sensitive to the property x which it is arranged to sense. The material 31 may be and/or comprise a pyro-electric polymer or ceramic if the property is temperature or a piezo-electric polymer if the property is pressure. The capacitance of the capacitive circuit C may thus be affected by the property x, giving a capacitance C(x) which may then be sensed and measured to give a measured value of x. The thickness of the film 32 may be at most of the order tens of microns (called thick film) and preferably in the order of sub-microns (thin film technology). The surface area (footprint) of the resonator 4 is expected to be in the range mm² to dm².

It is noted that multiple sensors 2 may be associated with the same array 4, in which case multiple sensors may be integrated with respective capacitive circuits C of the array 4 at different positions along the transfer path formed by the array.

FIG. 4 illustrates the transfers within the sensor arrangement 1 during operation thereof. The resonator array 4 has a fixed natural frequency fₒ which is tuned to a natural frequency f of the sensor 2, which natural frequency f of the sensor is dependent on the property x of the environment. For instance, the fixed natural frequency fₒ of the resonator array 4 may be within the range of 10 kHz to 100 MHz. The fixed natural frequency fₒ is typically tuned to the sensor unit frequency f(x) at a certain reference point x=xₒ, whereby changes in the property x may propagate along the array 4 to be detected by the detector 3.

Thus, power 42 can be transferred from the electrical power source 6 to the sensor 2 via the array 4, and sensor signals 41 can be transferred from the sensor 2 to the detector 3 via the same array 4. There is thus no need for an antenna or galvanic contact with the sensor to obtain the signals 41 there from.

FIG. 5 schematically illustrates that an embodiment of the sensor arrangement 1 can be comprised in an electrical device 1, e.g. a HV device.

FIG. 6 illustrates a controller 7 of the sensor arrangement 1. The controller 7 comprises processing circuitry 61 e.g. a central processing unit (CPU). The processing circuitry 61 may comprise one or multiple processing units in the form of microprocessor(s). However, other suitable devices with computing capabilities could be comprised in the processing circuitry 61, e.g. an application specific integrated circuit (ASIC), a field programmable gate array (FPGA) or a complex programmable logic device (CPLD). The processing circuitry 61 is configured to run one or several computer program(s) or software (SW) 63 stored in a storage 62 of one or several storage unit(s) e.g. a memory. The storage unit is regarded as a computer program product as discussed herein, comprising computer-executable components of the SW 63 on a non-transitory computer readable medium, and may e.g. be in the form of a Random Access Memory (RAM), a Flash memory or other solid state memory, or a hard disk, or be a combination thereof. The processing circuitry 61 may also be configured to store data in the storage 62, as needed.

Embodiments of the present disclosure may be conveniently implemented using one or more conventional general purpose or specialized digital computer, computing device, machine, or microprocessor, including one or more processors 61, memory and/or computer readable storage media 62 programmed according to the teachings of the present disclosure. Appropriate software 63 coding can readily be prepared by skilled programmers based on the teachings of the present disclosure, as will be apparent to those skilled in the software art.

FIG. 7 is a flow chart of an embodiment of a method of the present disclosure. The method is for detecting a measured property x in an electrical device environment. The method comprises, by means of a resonator array 4 comprising an array of LC circuits 5, wirelessly transferring S1 power 42 from an electrical power source 6 to a sensor 2 in the environment, powering said sensor. The method also comprises, by means of the resonator array 4, wirelessly transferring S2 signals 41 indicating a measurement of the property x from the sensor 2 to a detector 3.

The present disclosure has mainly been described above with reference to a few embodiments. However, as is readily appreciated by a person skilled in the art, other embodiments than the ones disclosed above are equally possible within the scope of the present disclosure, as defined by the appended claims.

1. A high voltage, HV, electrical device comprising a sensor arrangement comprising:
a sensor configured to measure a property of the electrical device;
a detector configured to receive signals from the sensor;
an electrical power source; and
a resonator array comprising an array of LC circuits arranged equidistantly and galvanically isolated from each other along a transfer path, such as an axis, between the sensor and the detector and configured to wirelessly transfer power to the sensor from the electrical power source and to wirelessly transfer the sensor signals from the sensor to the detector.

2. The electrical device of claim 1, wherein the resonator array has a fixed natural frequency which is tuned to a natural frequency of the sensor which is dependent on the property of the environment, wherein the fixed natural frequency of the resonator array is within the range of 10 kHz to 100 MHz.

3. The electrical device of claim 1, wherein the sensor is arranged at a high electrical potential and the detector and/or the power source is/are arranged at a low electrical potential.

4. The electrical device of claim 1, wherein the detector comprises an impedance meter, comprising an impedance analyser.

5. The electrical device of claim 1, wherein the sensor is integrated with the resonator array.

6. The electrical device of claim 5, wherein the integrated sensor comprises a capacitor of an LC circuit of the resonator array.

7. The electrical device of claim 6, wherein the capacitor comprises a dielectric material which is sensitive to the property of the electrical device, and
wherein the dielectric material comprises a pyro-electric polymer or a ceramic responsive to the property being temperature and a piezo-electric polymer responsive to the property being pressure.

8. The electrical device of claim 1, wherein each LC circuit of the resonator array is printed on an electrically insulating film, preferably of a dielectric material.

9. The electrical device of claim 1, wherein the resonator array comprises a plurality of flat LC circuits co-axially arranged a predetermined distance from each other.

10. The electrical device of claim 1, wherein the resonator array comprises a plurality of co-planar flat LC circuits arranged side by side.

11. The electrical device of claim 1, wherein the property of the HV environment is any in the group of properties consisting of temperature, pressure, acceleration, moisture, acidity and oxygen level, preferably temperature or pressure, especially temperature.

12. The electrical device of claim 1, wherein the electrical device is a transformer.

13. A method of detecting a measured property in a high voltage, HV, electrical device, the method comprising:
by means of a resonator array comprising an array of LC circuits arranged equidistantly and galvanically isolated from each other along a transfer path, such as an axis, between a sensor and a detector, wirelessly transferring power from an electrical power source to the sensor, powering said sensor; and
by means of the resonator array, wirelessly transferring signals indicating a measurement of the property from the sensor to the detector.

14. A computer program product comprising computer-executable components for causing a controller to perform the method of claim 13 when the computer-executable components are run on processing circuitry comprised in the controller.

15. A high voltage, HV, electrical device comprising a sensor arrangement comprising:
a sensor configured to measure a property of the electrical device;
a detector configured to receive signals from the sensor; and
a resonator array comprising an array of LC circuits arranged equidistantly and galvanically isolated from each other along a transfer path, such as an axis, between the sensor and the detector and configured to wirelessly transfer power to the sensor and to wirelessly transfer the sensor signals from the sensor to the detector.

16. The electrical device of claim 15,
wherein the resonator array has a fixed natural frequency which is tuned to a natural frequency of the sensor which is dependent on the property of the environment, e.g. wherein the fixed natural frequency of the resonator array is within the range of 10 kHz to 100 MHz,
wherein the sensor is arranged at a high electrical potential and the detector and/or the power source is/are arranged at a low electrical potential.

17. The electrical device of claim 15,
wherein the sensor is integrated with the resonator array,
wherein the integrated sensor comprises a capacitor of an LC circuit of the resonator array,
wherein the capacitor comprises a dielectric material which is sensitive to the property of the electrical device, and
wherein the dielectric material comprises a pyro-electric polymer or a ceramic responsive to the property being temperature and a piezo-electric polymer responsive to the property being pressure.

18. The electrical device of claim 15, wherein each LC circuit of the resonator array is printed on an electrically insulating film that comprises a dielectric material.

19. The electrical device of claim 15, wherein the resonator array comprises a plurality of flat LC circuits co-axially arranged a predetermined distance from each other or a plurality of co-planar flat LC circuits arranged side by side.

20. The electrical device of claim 1, wherein the electrical device is a transformer.
